(19) United States
(12) Patent Application Publication
(10) Pub. No.: US 2015/0198302 A1
(43) Pub. Date: Jul. 16, 2015

(54) KEYBAORD LIGHT-EMITTING STRUCTURE

(71) Applicant: CHICONY POWER TECHNOLOGY CO., LTD., New Taipei City (TW)

(72) Inventors: Hsin-Chih LIANG, New Taipei City (TW); Pai-Hsiang WANG, New Taipei City (TW)

(73) Assignee: CHICONY POWER TECHNOLOGY CO., LTD., New Taipei City (TW)

(21) Appl. No.: 14/157,384

(22) Filed: Jan. 16, 2014

(51) Int. Cl. F21V 7/05; H05K 1/18; H01H 9/18; F21V 23/06

(52) U.S. Cl. CPC F21V 7/05; F21V 23/06; H05K 1/189; H01H 9/182; F21Y 2105/001

(57) ABSTRACT

A keyboard light-emitting structure mounted at a bottom side of a keyboard for illuminating the keyboard upon operation is disclosed to include a base module including a planar reflector, a planar light shield covering the planar reflector and having open spaces therein and a planar light guide sandwiched between the planar reflector and the planar light shield, and a light-emitting device including a flexible printed circuit board bonded to the planar reflector, a plurality of light-emitting components located at one end of the flexible printed circuit board and arranged in different directions within one respective opening of the planar reflector and a connection terminal located at an opposite end of the flexible printed circuit board and electrically connected with the circuit layout of the keyboard to an external power source.

### BACKGROUND OF THE INVENTION

1. Field of the Invention

The present invention relates to keyboard technology and more particularly, to a keyboard light-emitting structure mounted at a bottom side of a keyboard for illuminating the keyboard upon operation.

2. Description of the Related Art

Following fast development of the modern technology and electronic industry, various kinds of consumer electrical and electronic devices are created, bringing convenience to people. Different electrical or electronic devices have different configurations, designs and weights, and require different installation spaces. To facilitate mobility, mobile electronic devices, such as notebook computers, PDAs, tablet computers, smart phones and etc., have been created, and have appeared on the market. These mobile electronic devices commonly have light, thin, short and small characteristics and are highly portable.

To meet the requirements for mobile electronic devices having light, thin, short and small characteristics, printed circuit boards, electrical connectors, keyboards and other component parts must be made as smaller as possible. In consequence, the key caps of a keyboard for mobile electronic device must be arranged close to one another to reduce space occupation. Further, a keyboard may be equipped with a light-emitting structure capable of emitting light upon operation of the keyboard.

FIGS. 6 and 7 illustrate two prior art light-emitting computer keyboard designs. According to these two prior art designs, the keyboard A has an elongated or curved flexible printed circuit board B mounted in a partition board Al thereof. The flexible printed circuit board B carries a plurality of light-emitting components B1 that are spaced along the length of the flexible printed circuit board B. When the flexible printed circuit board B is electrically conducted, the light-emitting components B1 emit light through gaps between adjacent key caps of the keyboard A. According to these two prior art designs, the flexible printed circuit board B extends between two opposing front and rear sides of the keyboard A. Thus, the fabrication and installation of the flexible printed circuit board B are complicated, increasing the cost. Further, the arrangement of the flexible printed circuit board B occupies much internal space of the keyboard A and complicates the fabrication of the keyboard A.

Therefore, it is desirable to provide a keyboard light-emitting arrangement that eliminates the drawbacks of the aforesaid conventional designs.

### SUMMARY OF THE INVENTION

The present invention has been accomplished under the circumstances in view. It is therefore the main object of the present invention to provide a keyboard light-emitting structure, which is practical for use with a keyboard for any of a variety of mobile electronic devices having light, thin, short and small characteristics and, which facilitates economic fabrication and installation.

To achieve this and other objects of the present invention, a keyboard light-emitting structure of the invention comprises a base module and at least one light-emitting device. The base module comprises a planar reflector defining at least one opening, a planar light shield covering the planar reflector and comprising a plurality of light-shielding strips arranged in a crisscross pattern and a plurality of open spaces surrounded by the light-shielding strips, and a planar light guide sandwiched between the planar reflector and the planar light shield. Each light-emitting device comprises a flexible printed circuit board bonded to the planar reflector, a plurality of light-emitting components located at one end of the flexible printed circuit board and arranged in different directions within one respective opening of the planar reflector, and a connection terminal located at an opposite end of the flexible printed circuit board and suspending outside the base module and electrically connectable with the circuit layout of the matched keyboard to an external power source.

Further, the light-emitting components of each light-emitting device can be arranged in a sector-like, radial, rectangular or multilateral pattern.

Further, the connection terminal of each light-emitting device can be selectively made in the form of a set of metal contacts, a set of conducting pins, or an electrical connector.

Further, one opening of the planar reflector is disposed in vertical alignment with the space bar of the matched keyboard.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is an oblique top elevational view of a light-emitting keyboard in accordance with the present invention.

FIG. 2 is an exploded view of the light-emitting keyboard in accordance with the present invention.

FIG. 3 is schematic sectional exploded view of the light-emitting keyboard in accordance with the present invention.

FIG. 4 is a schematic applied view of the light-emitting keyboard in accordance with the present invention.

FIG. 5 is a schematic top view of an alternate form of the present invention.

FIG. 6 is a schematic top view of a light-emitting computer keyboard according to the prior art.

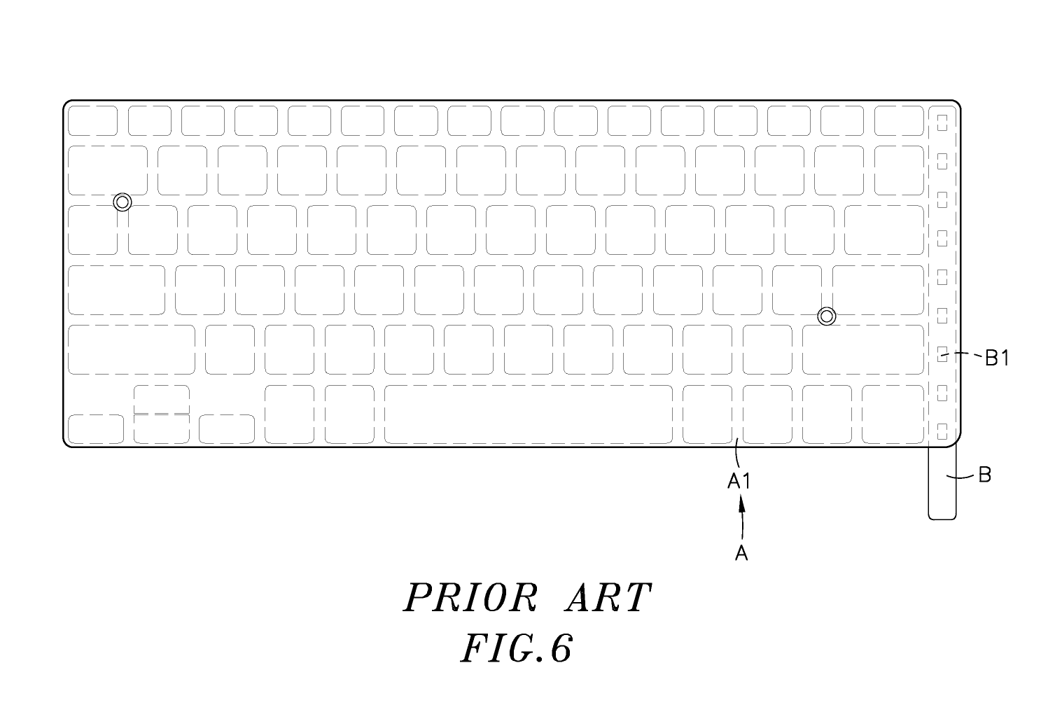

FIG. 7 is a schematic top view of another design of light-emitting computer keyboard according to the prior art.

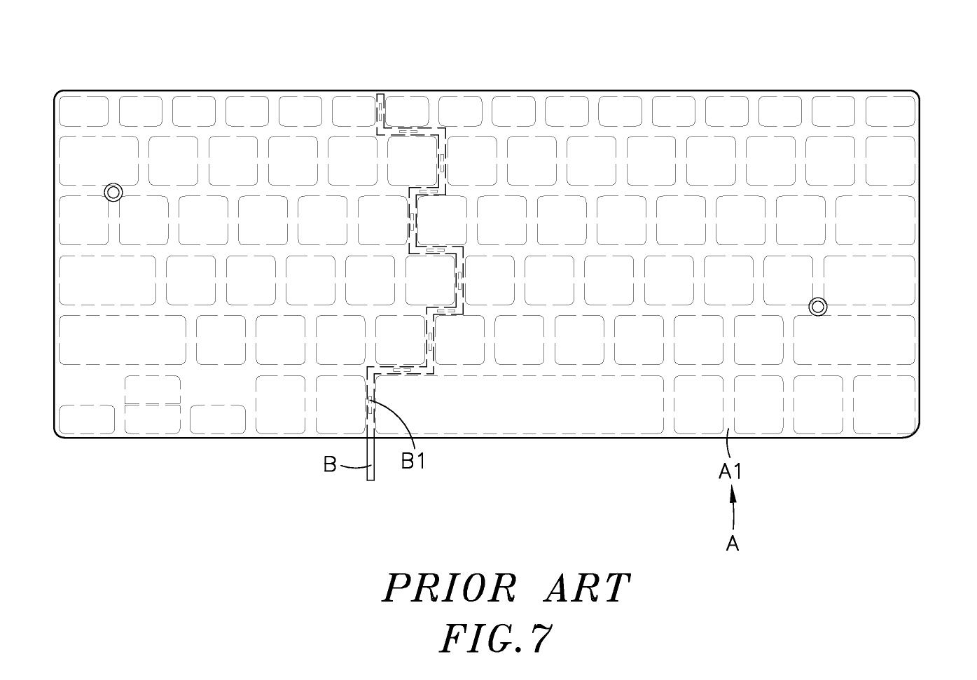

### DETAILED DESCRIPTION OF THE PREFERRED EMBODIMENT

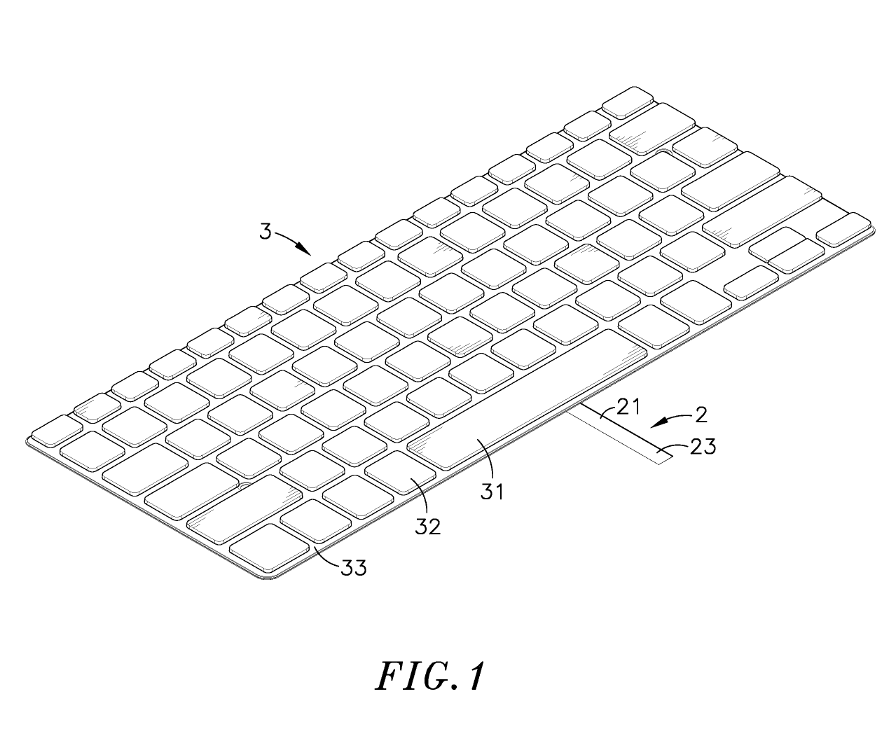

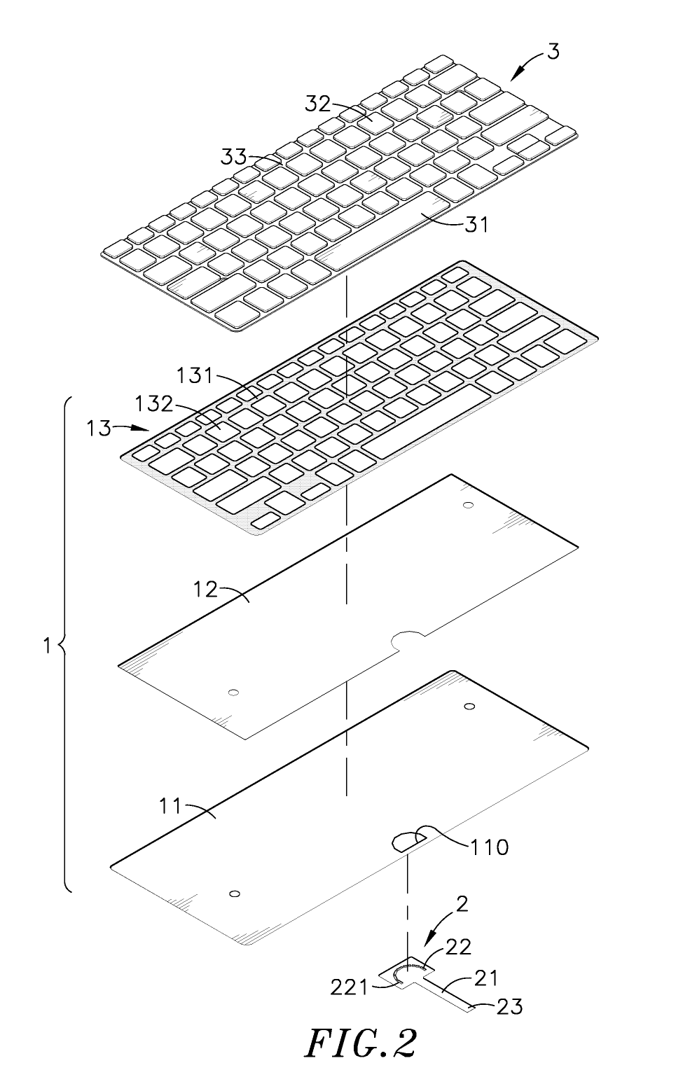

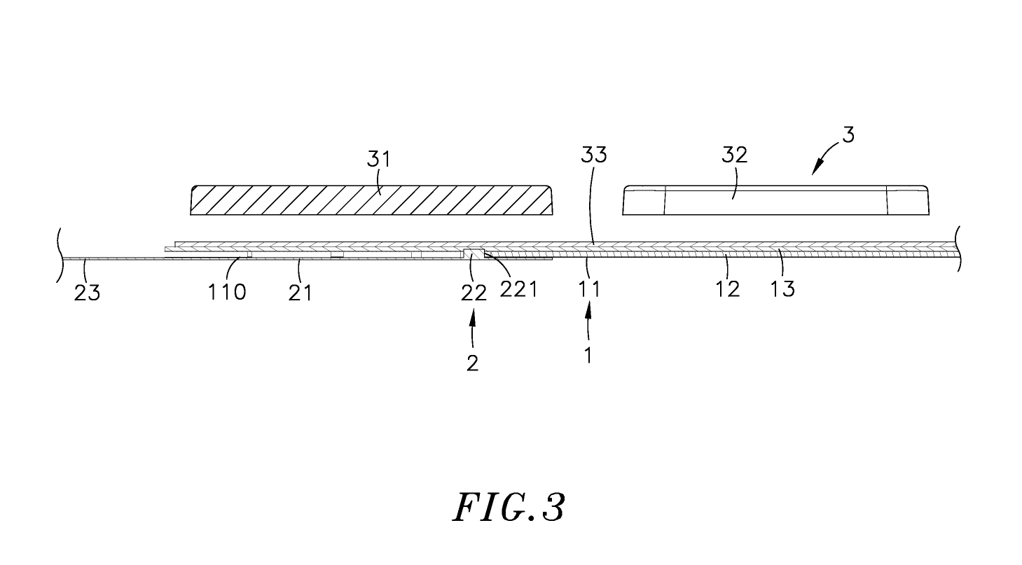

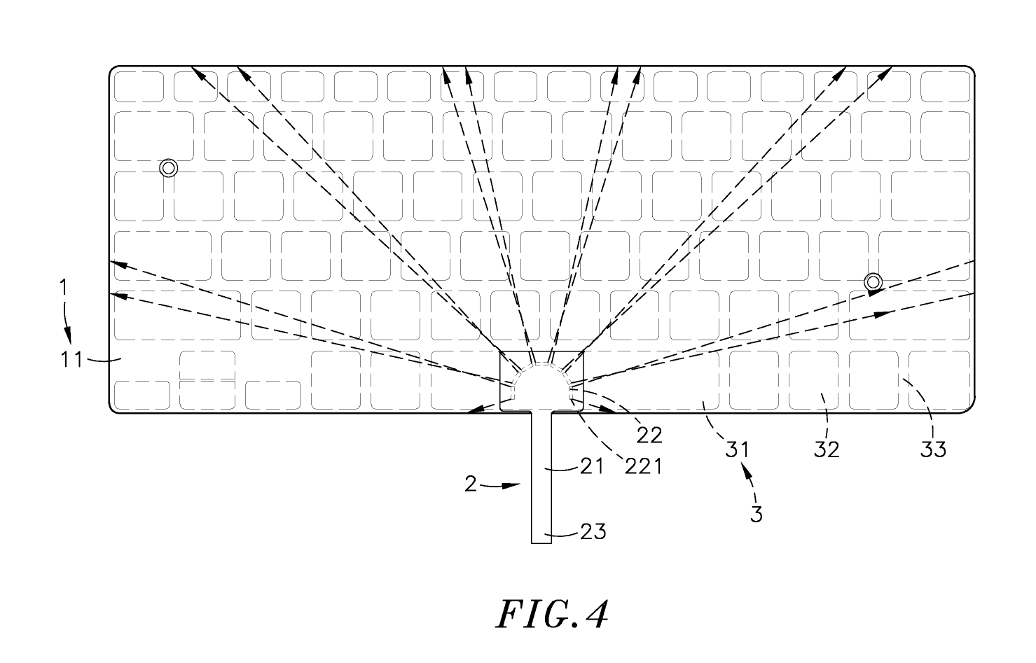

Referring to FIGS. 1-4, a keyboard light-emitting structure in accordance with the present invention is shown. The keyboard light-emitting structure comprises a base module 1, and at least one, for example, one light-emitting device 2.

The base module 1 comprises a planar reflector 11, a planar light guide 12 and a planar light shield 13. The planar reflector 11, the planar light guide 12 and the planar light shield 13 are arranged in a stack with the planar light guide 12 sandwiched in between the planar reflector 11 and the planar light shield 13. The planar reflector 11 has at least one, for example, one opening 110 cut through the opposing top and bottom surfaces thereof at a selected location near the border edge. The planar light shield 13 comprises a plurality of light-shielding strips 131 arranged in a crisscross pattern, and a plurality of open spaces 132 surrounded by the light-shielding strips 131.

The light-emitting device 2 comprises a flexible printed circuit board 21, a plurality of light-emitting components 22 located at one end of the flexible printed circuit board 21 and having light-emitting surfaces 221 thereof arranged in different directions, and a connection terminal 23 located at an opposite end of the flexible printed circuit board 21.

During installation, bond the light-emitting device 2 to the planar reflector 11 of the base module 1 to keep the light-emitting components 22 of the light-emitting device 2 in the opening 110 of the planar reflector 11 and to suspend the connection terminal 23 of the light-emitting device 2 outside the planar reflector 11. Thereafter, fixedly mount the base module 1 in a bottom side of a keyboard 3.

Further, the light-emitting surfaces 221 of the light-emitting components 22 of the light-emitting device 2 can be arranged in a sector, radial, rectangular or multilateral pattern for emitting light in different directions. Further, the light-emitting components 22 can be light-emitting diodes or electroluminescent cold-light chips. Further, the connection terminal 23 of the light-emitting device 2 can be a set of metal contacts or conducting pins, or an electrical connector for electrically connecting with the circuit layout of the keyboard 3 to an external power source to obtain the necessary working voltage for the working of the light-emitting components 22.

Further, because the light-emitting components 22 of the light-emitting device 2 is accommodated in the opening 110 near the border edge of the planar reflector 11 of the base module 1 and the connection terminal 23 is disposed outside the base module 1, the length of the flexible printed circuit board 21 of the light-emitting device 2 in the bottom side of the keyboard 3 is limited. Thus, the size of the flexible printed circuit board 21 of the light-emitting device 2 is minimized, saving the cost. Therefore, the keyboard light-emitting structure can be used with a keyboard for any of a variety of mobile electronic devices, such as notebook computer or PDA that has light, thin, short and small characteristics.

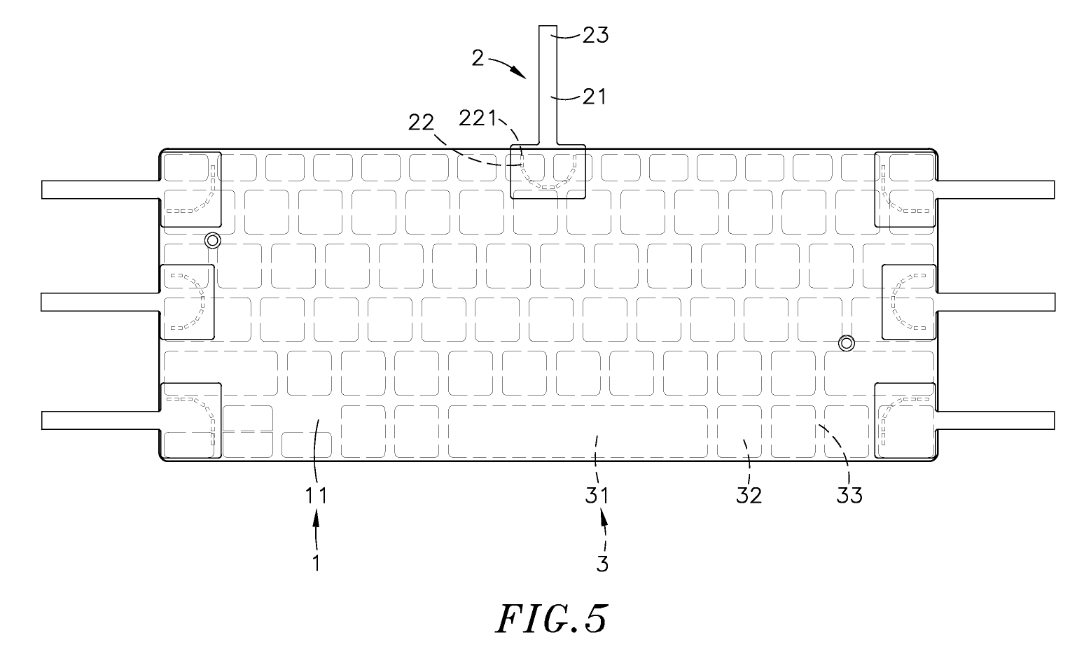

Referring to FIG. 5, in an alternate form of the present invention, multiple light-emitting devices 2 are respectively installed in respective openings in the planar reflector of the base module 1 around the border area thereof.

Referring to FIGS. 1-5 again, after the keyboard light-emitting structure is assembled with the keyboard 3, the connection terminal 23 of each light-emitting device 2 of the keyboard light-emitting structure is electrically connected with the circuit layout of the keyboard 3 to an external power source to obtain the necessary working voltage for the working of the light-emitting components 22 of each light-emitting device 2, and the light-shielding strips 131 and open spaces 132 of the planar light shield 13 are respectively kept in vertical alignment with the plaid 33 and key caps 32 (including the space bar 31) of the keyboard 3. Further, the plaid 33 of the keyboard 3 is light transmissive.

During operation of the keyboard 3, the light-emitting components 22 of each light-emitting device 2 are driven to emit light through the respective light-emitting surfaces 221 and the open spaces 132 of the planar light shield 13 toward the key caps 32 and space bar 31 of the keyboard 3 to illuminate the keyboard 3.

In conclusion, the invention provides a keyboard light-emitting structure comprising base module 1, and at least one, for example, one light-emitting device 2 mounted at a bottom side of a keyboard 3 for illuminating the keyboard 3 upon operation, wherein the base module 1 comprises a planar reflector 11 having at least one opening 110, a planar light shield 13 covering the planar reflector 11 and having a plurality of light-shielding strips 131 arranged in a crisscross pattern and a plurality of open spaces 132 surrounded by the light-shielding strips 131 and a planar light guide 12 sandwiched between the planar reflector 11 and the planar light shield 13; each light-emitting device 2 comprises a flexible printed circuit board 21 bonded to the planar reflector 11, a plurality of light-emitting components 22 located at one end of the flexible printed circuit board 21 and arranged in different directions within one respective opening 110 of the planar reflector 11, and a connection terminal 23 located at an opposite end of the flexible printed circuit board 21 and electrically connected with the circuit layout of the keyboard 3 to an external power source. Although particular embodiment of the invention have been described in detail for purposes of illustration, various modifications and enhancements may be made without departing from the spirit and scope of the invention. Accordingly, the invention is not to be limited except as by the appended claims.

What the invention claimed is:

1. A keyboard light-emitting structure mounted at a bottom side of a keyboard for illuminating said keyboard upon operation, comprising:
a base module comprising a planar reflector defining at least one opening, a planar light shield covering said planar reflector, said planar light shield comprising a plurality of light-shielding strips arranged in a crisscross pattern and a plurality of open spaces surrounded by said light-shielding strips, and a planar light guide sandwiched between said planar reflector and said planar light shield; and
at least one light-emitting device, each said light-emitting device comprising a flexible printed circuit board bonded to said planar reflector, a plurality of light-emitting components located at one end of said flexible printed circuit board and arranged in different directions within one respective said opening of said planar reflector, and a connection terminal located at an opposite end of said flexible printed circuit board and suspending outside said base module and electrically connected with a circuit layout of said keyboard to an external power source.

2. The keyboard light-emitting structure as claimed in claim 1, wherein said planar reflector comprises at least one said opening disposed in one lateral side thereof.

3. The keyboard light-emitting structure as claimed in claim 1, wherein the light-emitting components of each said light-emitting device are arranged in one of sector-like, radial, rectangular and multilateral patterns.

4. The keyboard light-emitting structure as claimed in claim 1, wherein the light-emitting components of each said light-emitting device are light-emitting diodes.

5. The keyboard light-emitting structure as claimed in claim 1, wherein said planar reflector comprises one said opening in vertical alignment with the space bar of said keyboard.

6. The keyboard light-emitting structure as claimed in claim 5, wherein the light-emitting components of each said light-emitting device are arranged in one of sector-like, radial, rectangular and multilateral patterns.

7. The keyboard light-emitting structure as claimed in claim 1, wherein said connection terminal of each said light-emitting device is selectively made in the form of a set of metal contacts, a set of conducting pins, or an electrical connector.
